(19) United States
(12) Patent Application Publication
(10) Pub. No.: US 2022/0325126 A1
(43) Pub. Date: Oct. 13, 2022

(54) INSULATING FILM FOR ELECTRONIC COMPONENTS AND METHOD OF PRODUCING INSULATING FILM FOR ELECTRONIC COMPONENTS

(71) Applicant: TAIYO INK MFG. CO., LTD., Hiki-gun (JP)

(72) Inventors: Yoshihiro ONO, Hiki-gun (JP); Manabu Akiyama, Hiki-gun (JP)

(73) Assignee: TAIYO INK MFG. CO., LTD., Hiki-gun (JP)

(21) Appl. No.: 17/709,491

(22) Filed: Mar. 31, 2022

(30) Foreign Application Priority Data
Mar. 31, 2021 (JP) 2021-061803

(51) Int. Cl. C09D 139/04; H01B 3/44

(52) U.S. Cl. CPC C09D 139/04; H01B 3/44

(57) ABSTRACT

Provided is an insulating film for electronic components which can attain a good matte feeling and has excellent visibility of a marker. The insulating film for electronic components is an insulating film for electronic components having a front surface and a back surface, in which a maximum peak height Rp (μm) and the maximum valley depth Rv (μm) of the front surface satisfy the following relational expressions: 0.5≤Rv/Rp≤2 and 1≤Rp+Rv≤4. It is also an insulating film for electronic components, in which the 85° gloss Gs (85°) and the 60° gloss Gs (60°) of the front surface satisfy the following relational expression: Gs (85°)≥2Gs (60°); and Gs (85°) is 70 or more and Gs (60°) is 30 or less.

### BACKGROUND OF THE INVENTION

### Field of the Invention

The present invention relates to an insulating film for electronic components, particularly to an insulating film provided on the surface of, for example, a printed wiring board and a method of producing the same.

### Background Art

In order to protect a conductor circuit and prevent solder from adhering to sites other than where soldering is required to insulate, an insulating film, which is also referred to as “solder resist film,” is formed on the surface of a printed wiring board. Mainstream methods as a method of forming an insulating film include: a method of forming an insulating film only on the desired site on a surface of a circuit board by applying a photosensitive resin composition onto the circuit board, drying it, and then carrying out exposure and development; and a method of forming an insulating film only on the desired site on a surface of a circuit board by laminating a film having a photosensitive resin layer, a so-called dry film, to the circuit board and carrying out exposure and development.

It has been known that by roughening the surface of the insulating film in a circuit board as described above, the solder adhesion resistance at the time of flow soldering and wiring concealment improve. In addition, the insulating film subjected to surface roughening has a moderately low gloss, thereby obtaining good design properties. Furthermore, since scratches are less likely to be seen on a roughened surface than on a glossy surface, quality control is also reasonable. In recent years, in a board for an IC package or the like, an insulating film has been roughened for the purpose of improving the adhesion of die attachment. For example, Patent Literature 1 proposes providing a certain number of dents per unit on the surface of a photosensitive film. Further, Patent Literature 2 suggests that a photosensitive film having a surface having a specific average spacing of unevenness is less likely to cause pattern collapse and can improve the yield of visual inspection.

As an aside, on the surface of an electronic circuit board, identification characters, symbols, and the like (markers) are printed with a marking ink for information on the mounting positions of electronic components to be mounted such that the information can be known in consideration of the subsequent mounting process of the electronic components. The marking ink used is a thermosetting ink and a UV curing ink for marking mainly formed by pattern printing or an alkaline developing type of ink for marking formed by exposure through a negative film and removal of an unexposed portion with an alkaline aqueous solution. Recently, a technique called laser marking has also been used, in which the color tone of an irradiated portion is changed by irradiating a laser beam to display characters and symbols. Further, Patent Literature 3 proposes providing a photosensitive resin layer on a layer having a concentration gradient of inorganic particles as a photosensitive film having excellent resolution and allowing the improvement of the yield of visual inspection.

### PRIOR ART DOCUMENTS

### Patent Documents

Patent Document 1: JP 2018-124452 A1
Patent Document 2: JP 2018-116255 A1
Patent Document 3: JP 2018-169537 A1

### SUMMARY OF THE INVENTION

### Technical Problem

When a marking ink is applied to a circuit board provided with a surface-roughened insulating film as described above, the marking ink may bleed due to the unevenness of the surface thereof, and the visibility of the marker may deteriorate. In addition, it may be difficult to print fine characters and symbols on the surface of the roughened insulating film.

The present invention has been made in view of the above problems. An object of the present invention is to provide an insulating film for electronic components which can attain a good matte feeling and has excellent visibility of a marker. Another object of the present invention is to provide a method of producing such an insulating film for electronic components.

### Solution to Problem

As a result of intensive studies, the present inventors found through the observation of the surface of the roughened insulating film that even when a matte feeling is visually recognized, as long as the maximum peak height and the maximum valley depth of the surface have a certain relationship, bleed can be reduced even after applying a marking ink. In addition, as a result of further studies of optical properties of the insulating film, the present inventors found that when the insulating film has a surface morphology with a certain gloss, a matte feeling can be obtained and marking ink bleed can be reduced. The present invention is based on such findings. That is, the gist of the present invention is as follows.

[1] An insulating film for electronic components having a front surface and a back surface, a maximum peak height Rp (μm) and the maximum valley depth Rv (μm) of the front surface satisfying the following relational expressions:

0.5≤Rv/Rp≤2, and

1≤Rp+Rv≤4.

[2] The insulating film for electronic components according to [1],

wherein the skewness Rsk (μm) of the front surface is −0.1 or more.

[3] A method of producing the insulating film for electronic components according to [1], comprising:

applying a curable resin composition to one side of a support to form a coating film;

curing the coating film to form an insulating film for electronic components; and

detaching the support,

wherein the skewness Rsk (μm) of the side of the support to which the curable resin composition is applied is 0.1 or less.

[4] The method of producing the insulating film for electronic components according to [3],

wherein when the contact angle of water on the side of the support to which the curable resin composition is applied is defined as B (°) and the contact angle of water on the surface of the insulating film obtained is defined as A (°), the following relational expression is satisfied:

A>B.

[5] An insulating film for electronic components having a front surface and a back surface,

wherein the 85° gloss Gs (85°) and the 60° gloss Gs (60°) of the front surface satisfy the following relational expression:

Gs(85°)≥2Gs(60°), and

wherein Gs (85°) is 70 or more and Gs (60°) is 30 or less.

[6] The insulating film for electronic components according to [1] or [5], comprises a heat-curing catalyst or a photocuring catalyst.
[7] The insulating film for electronic components according to [1] or [5], comprises a filler.

### Advantageous Effects of Invention

According to the present invention, by forming an insulating film in which the maximum peak height Rp and the maximum valley depth Rv of the surface satisfy a certain relationship, a good matte feeling can be obtained and marking ink bleed can be reduced. In addition, by forming an insulating film in which 85° gloss and 60° gloss of the surface have certain values, and both satisfy a specific relationship, a good matte feeling can be obtained and marking ink bleed can be reduced.

### DETAILED DESCRIPTION OF THE INVENTION

### First Embodiment

The insulating film for electronic components according to the first embodiment of the present invention will be described. The insulating film for electronic components according to the first embodiment is an insulating film for electronic components having a front surface and a back surface, wherein the maximum peak height Rp (μm) and the maximum valley depth Rv (μm) of the front surface satisfy the following relational expressions:

0.5≤Rv/Rp≤2, and

1≤Rp+Rv≤4.

Conventionally, the surface of an insulating film has been roughened in order to impart a matte feel. However, it has been difficult to impart a matte feeling and reduce marking ink bleed at the same time simply by setting the surface roughness Ra within a prescribed range. In the present invention, instead of focusing on the surface roughness Ra, the present inventors newly focused on the maximum peak height Rp and the maximum valley depth Rv and found that when the surface morphology satisfies the above expressions, a matte feeling can be imparted and marking ink bleed can be reduced at the same time. The reason for this is unclear, but it is assumed as follows. When the insulating film having a surface roughness morphology such that Rp+Rv (=Rz) is one or more further satisfies the relational expression of Rv/Rp≤2, the absolute value of the depth and the absolute value of the height of unevenness existing on the insulating film surface become infinitely equal. It is assumed that as the insulating film has such a surface roughness morphology, and the depth and the height of unevenness becomes substantially equal, the insulating film has dents where a marking ink cannot enter when the ink is applied, i.e., dents where air exists under the applied marking ink, which results in a state in which the insulating film supports the applied marking ink with points instead of the surface, thereby reducing the spread and bleeding of the marking ink. However, this is merely an assumption, and is not limited to this.

In the present invention, the maximum peak height Rp and the maximum valley depth Rv are values measured according to JIS B 0601:2001, which can be measured using a non-contact type surface roughness meter (e.g., shape measurement laser microscope (VX-100) manufactured by KEYENCE CORPORATION). Specifically, an observation application (VK-H1XV) is booted, a sample to be measured is placed statically on the XY stage, and the 50× objective lens is focused by autofocus in the shape measurement mode. The Z-axis is controlled as necessary to adjust the focus to the optimum position. Observation images are captured in the automatic measurement mode or the manual measurement mode. Next, an analysis application (VK-H1XA) is booted and measurement is started. As the measurement conditions, the evaluation range is set to 270 μm×202 μm. The Rp and Rv values of 10 evaluation points are measured at equal intervals from the center to the outside of the sample to be evaluated, and the averages of the respective values are defined as “maximum peak height Rp” and “maximum valley depth Rv” according to the present invention. Conditions other than the above are in accordance with JIS B 0601:2001.

In the present invention, when the value of Rv/Rp is less than 0.5 or more than 2 μm, a matte feeling can be obtained, but bleeding when the marking ink is applied cannot be reduced. In addition, in a case where the insulating film is formed by exposing a curable resin composition as described later, the resolution deteriorates, and fine patterning becomes difficult. Further, when the value of Rp+Rv (i.e., Rz) is less than 1 μm, it is difficult to obtain a matte feeling, while when the value of Rp+Rv exceeds 4 μm, bleeding when the marking ink is applied cannot be reduced. The value of Rv/Rp is preferably 1 μm or more and more preferably 1.2 to 2 μm. The value of Rp+Rv is preferably 1 to 4 μm and more preferably 1.5 to 3 μm.

The insulating film for electronic components according to the first embodiment is an insulating film having a matte feeling, and from the viewpoint of reducing marking ink bleed, the skewness Rsk of the insulating film surface is preferably −0.1 μm or more and more preferably −0.1 to 0.1 μm. The skewness Rsk described herein is an index of the symmetry of peaks and valleys on the rough surface and is the value measured in accordance with JIS B 0601:2001, which can be measured by using a non-contact type surface roughness meter (e.g., shape measurement laser microscope (VX-100) manufactured by KEYENCE CORPORATION). As a specific measurement method, an observation application (VK-H1XV) is booted, a sample to be measured is placed statically on the XY stage, and the 50× objective lens is focused by autofocus in the shape measurement mode. The Z-axis is controlled as necessary to adjust the focus to the optimum position. Observation images are captured in the automatic measurement mode or the manual measurement mode. Next, an analysis application (VK-H1XA) is booted and measurement is started. As the measurement conditions, the evaluation range is set to 270 μm×202 μm. The Rsk values of 10 evaluation points are measured at equal intervals from the center to the outside of the sample to be evaluated, and the average of the values is defined as “skewness Rsk” according to the present invention. Conditions other than the above are in accordance with JIS B 0601:2001.

In the insulating film for electronic components according to the first embodiment, the contact angle of water (hereinafter, also referred to as “contact angle A”) is preferably 75° or more and more preferably 80° to 90°. The insulating film for electronic components can be obtained by applying a curable resin composition on a support, exposing it, and then curing it as described later as an embodiment. By making the contact angle of water of the insulating film for electronic components higher than the contact angle of water of the support (hereinafter, also referred to as “contact angle B”), it is possible to further reduce marking ink bleed. It is to be noted that the contact angle described herein is defined in JIS R3257:1999, and refers to a contact angle measured using ion-exchanged water as water. The contact angle of water can be measured and analyzed by the perfect circle fitting method under the following conditions using DropMaster DM300 as a contact angle meter and FAMS (both manufactured by Kyowa Interface Science Co., Ltd.) as an integrated interface measurement and analysis system.

### [Measurement Conditions and Measurement Method]

First, boot the interface measurement analysis integrated system and start the CA/PD controller. At that time, select “Standard” for “Field of view” on the screen of the controller. Next, fill a plastic syringe with Ion-exchanged water, attach a stainless-steel needle (No. 22 gauge) to the tip of the syringe, and drop the water onto the surface of a test piece (the dry coating film surface). Make sure that the camera attached to the contact angle meter is in focus when dripping. Immediately after dripping, press the “Measurement” button on the controller screen.
Water to be used for measurement: Ion-exchanged water with a quality of treated water of 1 μS/cm or less produced by a system (Purelite PRO-0250-003 manufactured by Organo Corporation).
Amount of water dropped: 2 μL
Measurement temperature: 20° C.
Lens field of view: Standard

Subsequently, the contact angle immediately after dropping water is measured at any five points on the test piece placed horizontally, and the average value of the measurement results is defined as the contact angle of water. Here, the values of the contact angles at any five points are set to the values automatically calculated by pressing the “Measurement” button.

### Second Embodiment

Next, the insulating film for electronic components according to the second embodiment of the present invention will be described. The insulating film for electronic components according to the second embodiment is an insulating film for electronic components, wherein the 85° gloss Gs (85°) and the 60° gloss Gs (60°) measured in accordance with JIS Z 8741:1997 satisfy the following relational expression:

Gs(85°)≥2Gs(60°), and

wherein Gs (85°) is 70 or more and Gs (60°) is 30 or less.
In the present invention, a large number of insulating films for electronic components having various surface morphologies were prepared and subjected to gloss measurement. Accordingly, the gloss has certain values at incident angles of 60° and 85° of the insulating film for electronic components, and both satisfy a predetermined relationship. In other words, when a surface morphology that the 85° gloss Gs (85°) is twice or more the 60° gloss Gs (60°), the Gs (85°) is 70 or more, and the Gs (60°) is 30 or less is attained, a good matte feeling can be obtained and marking ink bleed can be reduced. The reason for this is unclear, but it is assumed as follows.

When the reflectances at both 85° and 60° are high, a diffuse reflection of light does not occur, and the insulating film can be visually recognized as having gloss. In comparison, when the reflectances at both 85° and 60° are low, light is diffusely reflected, and the insulating film loses its gloss feeling. Further, to achieve a high value of the 85° gloss, the insulating film surface mustn't be roughened, and to achieve a low value of the 60° gloss, the insulating film surface must be roughened. To achieve both of these contradictory states, it is necessary to have a surface morphology including shallow and fine unevenness. Even in a case where there are many shallow uneven portions, the probability that light with a high incident angle is diffusely reflected is low (in other words, a high 85° gloss). In addition, the presence of many fine uneven portions causes diffuse reflection in light having a low incident angle, resulting in a decrease in the gloss (in other words, a low 60° gloss). At that time, in the surface morphology in which the difference between the 85° gloss and the 60° gloss is double or more, it is assumed that shallower and finer unevenness exists. As a result, the insulating film has dents where a marking ink cannot enter when the ink is applied dents where air exists under the applied marking ink, which results in a state in which the insulating film supports the applied marking ink with points instead of the surface, thereby reducing the spread and bleeding of the marking ink. However, this is merely an assumption, and is not limited to this.

In the present invention, the gloss can be measured as the mirror gloss in accordance with JIS Z8741-1997. A specific method of measuring a gloss will be described by taking the 60° gloss as an example. As a premise, on a surface having a refractive index of 1.567, when the incident angle is 60°, the intensity of light having a reflectance of 10% is assumed to be 100, and the intensity of light having a reflectance of 0% is assumed to be 0. As a result, a value of 1/100 of the intensity of light having a reflectance of 10% corresponds to a gloss of 1. The intensity of light on the surface of a cured coating film provided on a substrate is measured using a reflectance meter with a geometric condition of an incident angle of 60°. Then, the gloss is calculated by dividing the obtained light intensity by a value of 1/100 of the above light intensity having a reflectance of 10%. Simply, a digital variable angle gloss meter (Micro-Tri-Gloss manufactured by BYK-Gardener Gmbh) can be used to measure the gloss at each angle of the surface of the cured coating film provided on the substrate. It is to be noted that “85° gloss (Gs (85°))” is the value of glosses when the measurement conditions are: incident angle=85°; and light-receiving angle=85°. Similarly, “60° gloss (Gs (60°))” is the value of gloss when the measurement conditions are: incident angle=60°; and light-receiving angle=600.

From the viewpoint of reducing marking ink bleed while obtaining a better matte feeling, Gs (85°)≥3Gs (60°) is preferable, and Gs (85°)≥4Gs (60°) is more preferable.

Further, from the viewpoint of reducing marking ink bleed while obtaining a better matte feeling, Gs (85°) is preferably 70 or more and more preferably in a range of 80 to 100.

Further, from the viewpoint of reducing marking ink bleed while obtaining a better matte feeling, Gs (60°) is preferably 20 or less.

### [Method of Evaluating Insulating Film for Electronic Components]

Hereinafter, a method of producing an insulating film for electronic components according to the first embodiment and the second embodiment of the present invention will be described.

The insulating film for electronic components of the present invention can be formed by applying a curable resin composition on a substrate, drying it, and then curing the curable resin composition with either or both light and heat. The curable resin composition may be cured by exposure and development to form a patterned insulating film for electronic components. An insulating film can be formed by preparing a dry film having a curable resin layer formed by applying a curable resin composition to one side of a support and drying it, attaching the dry film to a substrate such that the substrate and the curable resin layer are in contact with each other, photo-curing or heat-curing the curable resin layer, and then detaching the support. Further, an insulating film may be formed by attaching the dry film to a substrate such that the electronic component such as a circuit board and the curable resin layer are in contact with each other, detaching the support before and after exposure, and then curing the curable resin layer through development.

It is considered that the insulating films for electronic components according to the first embodiment and the second embodiment described above have a specific surface morphology that is not found in conventional insulating films. In other words, conventional surface-roughened insulating films having a matte feeling were formed by imparting a prescribed roughness morphology to the surface, but the insulating film of the present invention is considered to have a morphology including not only an uneven portion but also a certain flat portion. Such an insulating film having a surface morphology including an uneven portion and a certain flat portion may be produced by incorporating a prescribed surface morphology to the surface of the dry coating film of the curable resin composition using a transfer roller or the like or by using a dry film obtained by applying a curable resin composition to a support having a surface that has been processed into a specific shape in advance and drying it. Alternatively, an excellent insulating film can be produced more easily and conveniently by the following method. Hereinafter, a method of preferably producing an insulating film for electronic components as described above will be described.

### [Dry Film]

The insulating film for electronic components of the present invention can be obtained by photo-curing or heat-curing a curable resin layer using a dry film, or by curing a curable resin layer by exposure or development.

A dry film has a structure in which a support and a curable resin layer formed of a curable resin composition are laminated in this order. Here, the curable resin layer is a layer obtained by forming a coating of the curable resin composition and drying it, on which other layers such as a support and a protective film are not laminated in advance. Further, in the present invention, another film or the like may be provided in addition to the above components. For example, for the purpose of preventing dust and the like from adhering to the surface of the curable resin layer of the dry film and with consideration for the ease of handling of the dry film, a protective film may further be provided on the side of the dry film opposed to the side that is in contact with the support of the curable resin layer. Each of the components that compose the dry film will be described below. It is to be noted that the support refers to a support that is adhered to at least the curable resin layer when carrying out laminating such that the curable resin layer side of the dry film is in contact with the electronic component such as a wiring board. The support may be detached from the curable resin layer in the step after laminating. Meanwhile, the protective film optionally provided refers to a film that is detached from the curable resin layer before laminating when carrying out laminating such that the curable resin layer side of the dry film is in contact with the electronic component such as a wiring board and molding.

### [Support]

A support used for the dry film has roles of supporting a curable resin layer described later and of concurrently incorporating a prescribed surface morphology to the side of the curable resin layer that contact with the support at the time of exposure and development of the curable resin layer, as described later. Examples of the support may include those formed by adding a filler in a resin at the time of film formation of a film used for the support (kneading processing), performing matte coating (coating processing), or subjecting the film surface to blasting processing such as sand-blasting processing, hairline processing, chemical etching or the like. Of these, those subjected to coating processing can be preferably used. For example, a support having an intermediate layer containing particles on a support film can be used. The intermediate layer containing particles is not limited to a single layer, and may be laminated as a multi-layered layer of two or more layers.

As the supporting film that constitutes the support, commonly used known film can be used with no limitation. For example, films composed of thermoplastic resins such as polyester films such as polyethylene terephthalate or polyethylene naphthalate, polyimide films, polyamide-imide films, polypropylene films, or polystyrene films can be suitably used. Of these, polyester films can be suitably used from the viewpoint of thermal resistance, mechanical strength, ease of handling, and the like.

In addition, for the purpose of improving the strength, films stretched in a uniaxial direction or a biaxial direction are preferably used as the thermoplastic resin film described above.

As the particles that contained in the intermediate layer, commonly used known particles such as inorganic particles and organic particles can be used. Examples thereof include silica, barium sulfate, and titanium oxide, and they can be used solely: or two or more kinds can be used in combination. Of these, silica is preferable from the viewpoint of cost and availability.

The average primary particle size of the particles is preferably 0.1 to 10 μm. By setting the above range, it is possible to suppress visible scratches and improve the resolution at an even higher level. Further, it is preferable that the maximum particle size is set to the upper limit of the film thickness of the intermediate layer. It is to be noted that the average primary particle size described herein refers to a value obtained by arithmetically averaging the particle sizes of 10 particles randomly selected from a scanning electron microscope image captured after dispersing the particles contained in the intermediate layer in a solvent by ultrasonic waves to disaggregate the particles and drying them to remove the solvent.

It is preferable that the intermediate layer containing the particles as described above contains at least one of a melamine and a melamine compound. This is preferable because by using a dry film obtained by applying a curable resin composition to a support containing at least one of a melamine and a melamine compound in the intermediate layer and drying the mixture, the influence on the surface of the dry film can be suppressed even by a strong impact or pressure when the substrate on which the dry film is laminated is layered. Further, it is preferable that the melamine and the melamine compound contained in the intermediate layer of the support are contained in a large amount on the side in contact with the coating film of the curable resin composition (i.e., the curable resin layer).

As the melamine and the melamine compound, those which are known and commonly used can be used. In addition, in the present invention, the melamine compound also includes a mixture of the melamine compound and other substances. It is to be noted that the term “melamine” according to the prevent invention refers to a resin cured by polycondensation of melamine(2,4,6-triamino-1,3,5-triazine) and formaldehyde, which is a concept including: methylol melamine that is an initial reaction product of such melamine and formaldehyde; and alkylated methylol melamine that is an alkylated product thereof. Examples of the melamine also include modified melamines such as methylated methylol melamine, propylated methylol melamine, butylated methylol melamine, and isobutylated methylol melamine. Denatured melamines such as melamine (meth)acrylates are also included.

The melamine compound is a mixture of the above melamine and a different resin such as an acrylic resin, an epoxy resin, or an alkyd resin, and examples thereof include acrylic melamine, alkyd melamine, polyester melamine, and epoxy melamine. Of these, acrylic melamine and epoxy melamine are preferable, and acrylic melamine is more preferable, because more excellent impact resistance can be obtained. The acrylic melamine mentioned herein is a mixture of an acrylic resin and a melamine resin, and refers to a type of resin in which the acrylic resin is cured with the melamine resin. Specific examples of the acrylic melamine include ACRYDIC 54-172-60, A-322, A-405, and A-452 manufactured by DIC Corporation.

The intermediate layer containing the particles can be formed by dissolving the melamine and the melamine compound described above in an appropriate solvent, blending the inorganic particles therein to prepare a coating liquid, applying the coating liquid on a supporting film, and drying the coating. The amount of the inorganic particles blended is preferably 100 to 200 parts by mass and more preferably 110 to 190 parts by mass based on 100 parts by mass of the melamine and the melamine compound.

An anti-sticking treatment may be performed on the side of the support on which the curable resin layer is applied. For example, a coating liquid prepared by dissolving or dispersing an anti-sticking agent such as a wax, a silicone wax, a silicone-based resin into an appropriate solvent can be applied on and dried the surface of the support by a coating method such as a roll coating method, a spray coating method or a known means such as a gravure printing method or a screen printing method, thereby performing the anti-sticking treatment. Further, these anti-sticking agents may be contained in the intermediate layer containing the above-mentioned particles.

The thickness of the support is not in particular restricted and is selected as appropriate in a range of approximately 10 to 150 μm according to the application.

The skewness Rsk of the side of the support on which the curable resin composition is applied is preferably 0.1 μm or less and more preferably 0 to 0.1 μm from the viewpoint of obtaining an insulating film for reducing marking ink bleed.

The contact angle of water on the side of the support on which the curable resin composition is applied is preferably lower than the contact angle of water of the insulating film for electronic components, and more preferably 5° to 10° lower than the same, from the viewpoint of reducing marking ink bleed.

### [Curable Resin Layer]

In a case where the curable resin layer provided on at least one side of the support is photosensitive, it is subjected to patterning by exposure and development of the dry film to be an insulating film (solder resist layer) provided on an electronic component such as a circuit board. To form such a curable resin layer, a curable resin composition, for example, a conventionally known solder resist ink or the like, can be used without limitation. An example of a curable resin composition that can be preferably used to form the curable resin layer of the dry film according to the present invention will be described below.

In the present invention, the curable resin composition preferably contains at least an alkali-soluble resin, a photopolymerizable monomer, and a photocuring catalyst when imparting photosensitivity. Hereinafter, each component constituting the curable resin composition will be described.

The alkali-soluble resin is a component that is cured via polymerization or crosslinking by light irradiation, and as it has the alkaline development property, it can form an insulating film for electronic components in a desired pattern by exposure and development. As the alkali-soluble resin, various conventionally known photosensitive resins having a carboxyl group in the molecule can be preferably used. As the curable resin composition contains a carboxyl group-containing resin, the alkaline development property can be imparted to the curable resin composition. A carboxyl group-containing photosensitive resin having a (meth)acryloyl group in the molecule is particularly preferable from the viewpoint of photocurability and development resistance. The (meth)acryloyl group is preferably derived from acrylic acid or methacrylic acid or a derivative thereof. In a case where only a carboxyl group-containing resin having no (meth)acryloyl group is used, it is required to be used in conjunction with a compound having plural ethylenically unsaturated groups in the molecule described later, i.e., a photopolymerizable monomer, for the purpose of making the composition photocurable. Specific examples of the carboxyl group-containing resin include compounds as described below (may be either oligomers or polymers). It is to be noted that the term (meth)acryloyl group, when used herein, is a generic term of an acryloyl group, a meta-acryloyl group, and a mixture thereof; and the same is hereinafter applied to other similar expressions.

(1) A carboxyl group-containing resin obtained by copolymerization of an unsaturated carboxylic acid such as (meth)acrylic acid with an unsaturated group-containing compound such as styrene, α-methylstyrene, lower alkyl (meth)acrylate, or isobuthylene.
(2) A carboxyl group-containing urethane resin obtained by a polyaddition reaction of a diisocyanate such as aliphatic diisocyanate, branched aliphatic diisocyanate, alicyclic diisocyanate, or aromatic diisocyanate, with a carboxyl group-containing dialcohol compound such as dimethylolpropionic acid or dimethylolbutanoic acid and a diol compound such as polycarbonate polyol, polyether polyol, polyester polyol, polyolefin polyol, acrylic polyol, bisphenol A alkylene oxide adduct diol, or a compound having a phenolic hydroxyl group and an alcoholic hydroxyl group.
(3) A carboxyl group-containing photosensitive urethane resin obtained by a polyaddition reaction of diisocyanate with (meta)acrylate of a bifunctional epoxy resin such as bisphenol A type epoxy resin, hydrogenated bisphenol A type epoxy resin, bisphenol F type epoxy resin, bisphenol S type epoxy resin, bixylenol type epoxy resin, or biphenol type epoxy resin or a partially modified acid anhydrid thereof, a carboxyl group-containing dialcohol compound, and a diol compound.
(4) A carboxyl group-containing photosensitive urethane resin obtained by adding a compound having one hydroxyl group and one or more (meth)acryloyl groups in the molecule such as hydroxyalkyl (meth)acrylate during synthesis of the resin in (2) or (3) above to be terminally (meth)acrylated.
(5) A carboxyl group-containing photosensitive urethane resin obtained by adding a compound having one isocyanate group and one or more (meth)acryloyl groups in the molecule such as equimolar reaction product of isophorone diisocyanate and pentaerythritol triacrylate during synthesis of the resin in (2) or (3) above to be terminally (meth)acrylated.
(6) A carboxyl group-containing photosensitive resin obtained by bringing a bifunctional (solid) epoxy resin or a (solid) epoxy resin with two or more functionalities into reaction with (meth)acrylic acid and adding a dibasic acid anhydride to the hydroxyl group present in a side chain.
(7) A carboxyl group-containing photosensitive resin obtained by bringing a multifunctional epoxy resin into reaction with (meth)acrylic acid and adding a dibasic acid anhydride to the generated hydroxyl group, which multifunctional epoxy resin is obtained by epoxidation of a hydroxyl group of bifunctional (solid) epoxy resin with epichlorohydrin.
(8) A carboxyl group-containing polyester resin obtained by bringing a bifunctional oxetane resin into reaction with dicarboxylic acid such as adipic acid, phthalic acid, or hexahydrophthalic acid and adding a dibasic acid anhydride such as phthalic anhydride, tetrahydrophthalic anhydride, or hexahydrophthalic anhydride to the generated primary hydroxyl group.
(9) A carboxyl group-containing photosensitive resin obtained by bringing an epoxy compound having plural epoxy groups in one molecule into reaction with a compound having at least one alcoholic hydroxyl group and one phenolic hydroxyl group in one molecule, such as p-hydroxyphenethyl alcohol, and an unsaturated group-containing monocarboxylic acid such as (meth)acrylic acid, and bringing the alcoholic hydroxyl group of the obtained reaction product into reaction with a polybasic anhydride such as maleic anhydride, tetrahydrophthalic anhydride, trimellitic anhydride, pyromellitic anhydride, or adipic acid.
(10) A carboxyl group-containing photosensitive resin obtained by bringing a compound having plural phenolic hydroxyl groups in one molecule into reaction with alkylene oxide such as ethylene oxide or propylene oxide; bringing the obtained reaction product into reaction with an unsaturated group-containing monocarboxylic acid; and bringing the obtained reaction product into reaction with a polybasic anhydride.
(11) A carboxyl group-containing photosensitive resin obtained by bringing a compound having plural phenolic hydroxyl groups in one molecule into reaction with a cyclic carbonate compound such as ethylene carbonate or propylene carbonate; bringing the obtained reaction product into reaction with an unsaturated group-containing monocarboxylic acid; and bringing the obtained reaction product into reaction with a polybasic anhydride.
(12) A carboxyl group-containing photosensitive resin obtained by further adding a compound having one epoxy group and one or more (meth)acryloyl groups in one molecule to the above resin in any of (1) to (11).

The alkali-soluble resin that can be used in the present invention is not limited to those listed above. In addition, one kind of the alkali-soluble resin listed above may be used alone, or two or more kinds may be mixed and used.

The weight average molecular weight of the alkali-soluble resin varies in resin backbone, and in general in a range of 2,000 to 150,000 and preferably in a range of 5,000 to 100,000. By using an alkali-soluble resin having a weight average molecular weight of 2,000 or more, resolution and tack-free performance can be improved. Further, by using an alkali-soluble resin having a weight average molecular weight of 150,000 or less, development properties and storage stability can be improved.

The amount of the alkali-soluble resin combined in the curable resin composition is preferably 20% to 60% by mass based on the total amount of the resin composition in terms of solid content. By making the amount 20% by mass or more, the coating film strength can be improved. In addition, by making the amount 60% by mass or less, an appropriate viscosity is attained and the processability improves. More preferably, the amount is 30% to 50% by mass.

The photopolymerizable monomer contained in the curable resin composition is a monomer having a photopolymerizable group composed of a (meth)acryloyl group. Examples of such a photopolymerizable monomer include commonly used known polyester (meth)acrylate, polyether (meth)acrylate, urethane (meth)acrylate, carbonate (meth)acrylate, and epoxy (meth)acrylate. To be specific, at least one selected as appropriate from the following can be used: hydroxyalkyl acrylates such as 2-hydroxyethyl acrylate or 2-hydroxy propyl acrylate; diacrylates of glycol such as ethylene glycol, methoxytetra ethylene glycol, polyethylene glycol, or propylene glycol; acrylamides such as N,N-dimethyl acrylamide, N-methylolacrylamide, or N,N-dimethylamino propyl acrylamide; amino alkyl acrylates such as N,N-dimethylamino ethyl acrylate or N,N-dimethylamino propyl acrylate; polyacrylates such as polyalcohol such as hexanediol, trimethylolpropane, pentaerythritol, dipentaerythritol, or tris-hydroxyethyl isocyanurate, or an ethylene oxide adduct, propylene oxide adduct, or ε-caprolactone adduct thereof; polyacrylates such as phenoxy acrylate, bisphenol A diacrylate, and an ethylene oxide adduct or propylene oxide adduct of those phenols; polyacrylates of glycidyl ether such as glycerin diglycidyl ether, glycerin triglycidyl ether, trimethylolpropane triglycidyl ether, or triglycidyl isocyanurate; and, besides the above, acrylates obtained by subjecting polyols such as polyether polyol, polycarbonate diol, hydroxyl-terminated polybutadiene, or polyester polyol to direct acrylation or urethane acrylation via diisocyanate, and melamine acrylates; and each of methacrylates corresponding to the above-mentioned acrylates. Such a photopolymerizable monomer can also be used as a reactive diluent.

An epoxy acrylate resin obtained by bringing a polyfunctional epoxy resin such as a cresol novolak-type epoxy resin into reaction with acrylic acid, an epoxyurethane acrylate compound obtained by further bringing the hydroxyl group of the epoxy acrylate resin into reaction with a hydroxy acrylate such as pentaerythritol triacrylate and a halfurethane compound of diisocyanate such as isophorone diisocyanate, and the like may be used as the photopolymerizable monomer. Such an epoxy acrylate-based resin can improve the photocurability without decreasing the property of drying to set to touch.

In a case where an alkali-soluble resin is contained in the curable resin composition, the amount of the photopolymerizable monomer combined is preferably 0.2 to 60 parts by mass and more preferably 0.5 to 50 parts by mass based on 100 parts by mass of the alkali-soluble resin in terms of solid content. By making the amount of the photopolymerizable monomer 0.2 parts by mass or more, the photocurability of the photocurable resin composition improves. In addition, by making the amount 60 parts by mass or less, the hardness of an insulating film for electronic components can be improved.

The photocuring catalyst contained in the curable resin composition is for reacting the above alkali-soluble resin or photopolymerizable monomer by exposure. Any known photocuring catalyst can be used. One kind of photocuring catalyst may be solely used or two or more kinds may be used in combination.

Specific examples of the photocuring catalyst can include: bisacylphosphine oxides such as bis-(2,6-dichlorobenzoyl)phenylphosphine oxide, bis-(2,6-dichlorobenzoyl)-2,5-dimethylphenylphosphine oxide, bis-(2,6-dichlorobenzoyl)-4-propylphenylphosphine oxide, bis-(2,6-dichlorobenzoyl)-1-naphthylphosphine oxide, bis-(2,6-dimethoxybenzoyl)phenylphosphine oxide, bis-(2,6-dimethoxybenzoyl)-2,4,4-trimethylpentylphosphine oxide, bis-(2,6-dimethoxybenzoyl)-2,5-dimethylphenylphosphine oxide, and bis-(2,4,6-trimethylbenzoyl)-phenylphosphine oxide; monoacylphosphine oxides such as 2,6-dimethoxybenzoyl diphenylphosphine oxide, 2,6-dichlorobenzoyl diphenylphosphine oxide, 2,4,6-trimethylbenzoyl phenylphosphinic acid methyl ester, 2-methylbenzoyl diphenylphosphine oxide, pivaloyl phenylphosphinic acid isopropyl ester, and 2,4,6-trimethylbenzoyl diphenylphosphine oxide; hydroxyacetophenones such as phenyl(2,4,6-trimethylbenzoyl)ethyl phosphinate, 1-hydroxy-cyclohexyl phenylketone, 1-[4-(2-hydroxyethoxy)-phenyl]-2-hydroxy-2-methyl-1-propane-1-one, 2-hydroxy-1-{4-[4-(2-hydroxy-2-methyl-propionyl)-benzyl]phen yl}-2-methyl-propane-1-one, and 2-hydroxy-2-methyl-1-phenylpropane-1-one; benzoins such as benzoin, benzyl, benzoin methyl ether, benzoin ethyl ether, benzoin n-propyl ether, benzoin isopropyl ether, and benzoin n-butyl ether; benzoin alkyl ethers; benzophenones such as benzophenone, p-methylbenzophenone, Michler's ketone, methylbenzophenone, 4,4′-dichlorobenzophenone, and 4,4′-bisdiethylaminobenzophenone; acetophenones such as acetophenone, 2,2-dimethoxy-2-phenylacetophenone, 2,2-diethoxy-2-phenylacetophenone, 1,1-dichloroacetophenone, 1-hydroxycyclohexyl phenylketone, 2-methyl-1-[4-(methylthio)phenyl]-2-morpholino-1-propanon, 2-benzyl-2-dimethylamino-1-(4-morpholinophenyl)-butanone-1, 2-(dimethylamino)-2-[(4-methylphenyl)methyl)-1-[4-(4-morpho linyl)phenyl]-1-butanone, and N,N-dimethylaminoacetophenone; thioxanthones such as thioxanthone, 2-ethyl thioxanthone, 2-isopropyl thioxanthone, 2,4-dimethyl thioxanthone, 2,4-diethyl thioxanthone, 2-chlorothioxanthone, and 2,4-diisopropyl thioxanthone; anthraquinones such as anthraquinone, chloroanthraquinone, 2-methylanthraquinone, 2-ethylanthraquinone, 2-tert-butylanthraquinone, 1-chloroanthraquinone, 2-amylanthraquinone, and 2-aminoanthraquinone; ketals such as acetophenone dimethyl ketal and benzyl dimethyl ketal; benzoic acid esters such as ethyl-4-dimethylaminobenzoate, 2-(dimethylamino)ethyl benzoate, and p-dimethylbenzoic acid ethyl ester; oxime esters such as 1,2-octanedione,1-[4-(phenylthio)-,2-(O-benzoyloxime)], ethanone, 1-[9-ethyl-6-(2-methylbenzoyl)-9H-carbazole-3-yl]-,1-(0-acetyl oxime); titanocenes such as bis(η5-2,4-cyclopentadiene-1-yl)-bis(2,6-difluoro-3-(1H-pyrrole-1-yl)phenyl)titanium, bis(cyclopentadienyl)-bis[2,6-difluoro-3-(2-(1-pyl-1-yl)ethyl)phe nyl]titanium; and phenyldisulfide 2-nitrofluorene, butyroin, anisoisoethyl ether, azobisisobutyronitrile, and tetramethylthiuram disulfide.

Examples of commercially available α-aminoacetophenone-based photocuring catalysts include Omnirad 907, 369, 369E, and 379 manufactured by IGM Resins B.V. In addition, examples of commercially available acylphosphine oxide-based photocuring catalysts include Omnirad TPO H and 819 manufactured by IGM Resins B.V. Examples of commercially available oxime ester-based photocuring catalysts include: Irgacure OXE01 and OXE02 manufactured by BASF Japan Ltd.; N-1919, and Adeka Arkls NCI-831 and NCI-831E manufactured by ADEKA Corporation; and TR-PBG-304 manufactured by TRONLY.

Besides, examples include carbazole oxime ester compounds described in Japanese Patent Application Laid-Open Publication No. 2004-359639, Japanese Patent Application Laid-Open Publication No. 2005-097141, Japanese Patent Application Laid-Open Publication No. 2005-220097, Japanese Patent Application Laid-Open Publication No. 2006-160634, Japanese Patent Application Laid-Open Publication No. 2008-094770, Japanese Translated PCT Patent Application Laid-Open No. 2008-509967, Japanese Translated PCT Patent Application Laid-open No. 2009-040762, and Japanese Patent Application Laid-Open Publication No. 2011-80036.

In a case where an alkali-soluble resin is contained in the curable resin composition, the amount of the photocuring catalyst combined is preferably 0.1 to 20 parts by mass, more preferably 0.5 to 18 parts by mass, and still more preferably 1 to 15 parts by mass based on 100 parts by mass of the alkali-soluble resin in terms of solid content. In a case where the amount is 0.1 parts by mass or more, the photocurability of the resin composition becomes good, and the coating film characteristics such as chemical resistance also become good. Meanwhile, in a case where the amount is 20 parts by mass or less, light absorption on the surface of the insulating film for electronic components (solder resist layer) improves and the deep curability does not easily decrease.

In conjunction with the above photocuring catalyst, a photoinitiation auxiliary agent or a sensitizer may be used. Examples of the photoinitiation auxiliary agent or the sensitizer can include a benzoin compound, a thioxanthone compound, a ketal compound, a benzophenone compound, a tertiary amine compound, and a xanthone compound. It is particularly preferable to use a thioxanthone compound such as 2,4-dimethyl thioxanthone, 2,4-diethyl thioxanthone, 2-chlorothioxanthone, 2-isopropyl thioxanthone, or 4-isopropyl thioxanthone. By containing the thioxanthone compound, the curability in deep portions can be improved. These compounds may in some cases be used as the photocuring catalyst but are preferably used in conjunction with the photocuring catalyst. Further, one kind of the photoinitiation auxiliary agent or the sensitizer may be used solely; or two or more kinds may be used in combination.

It is to be noted that because these photocuring catalyst, photoinitiation auxiliary agent, and sensitizer absorb a specific wavelength, they may in some cases function as ultraviolet absorbents because of decreased sensitivity. Yet, these are not used only for the purpose of improving the sensitivity of the resin composition. Light with a specific wavelength can be absorbed as necessary such that the photoreactivity of the surface can be increased. The line shape and opening of the resist pattern can be changed to a vertical shape, a tapered shape, or a reversed tapered shape. Besides, accuracy of the width of line and a diameter of opening can be improved.

In the present invention, in a case where the curable resin composition is thermosetting, it contains a thermosetting component. Further, even in a case where it is photosensitive, it may contain a thermosetting component in addition to the components described above. By containing the thermosetting component in the curable resin composition, the thermal resistance of the insulating film for electronic components can be improved. As the thermosetting component, a known thermosetting component, for example, an epoxy compound, an oxetane compound, an amino resin such as an episulfide resin, melamine resin, or benzoguanamine derivative, an isocyanate compound, or a blocked isocyanate compound can be used. A particularly preferable thermosetting component is a thermosetting component having plural cyclic ether groups or cyclic thioether groups (hereinafter, shortened to cyclic (thio)ether groups) in the molecule. One kind of thermosetting component can be used solely; or two or more kinds can be used in combination.

The above thermosetting component having plural cyclic (thio)ether groups in the molecule include a compound having plural groups in the molecule, which groups are 3-, 4-, or 5-membered cyclic (thio)ether groups; and examples of thereof include a compound having plural epoxy groups in the molecule, that is, a polyfunctional epoxy compound; a compound having plural oxetanyl groups in the molecule, that is, a polyfunctional oxetane compound; and a compound having plural thioether groups in the molecule, that is, an episulfide resin.

Examples of epoxy resins include bisphenol A type epoxy resin, bisphenol F type epoxy resin, hydrogenated bisphenol A type epoxy resin, brominated bisphenol A type epoxy resin, bisphenol S type epoxy resin, phenol novolac type epoxy resin, cresol novolac type epoxy resin, novolac type epoxy resin of bisphenol A, biphenyl type epoxy resin, naphthalene type epoxy resin, dicyclopentadiene type epoxy resin, and triphenylmethane type epoxy resin.

Examples of commercially available epoxy resins include: jER 828, 806, 807, YX8000, YX8034, and 834 manufactured by Mitsubishi Chemical Corporation; YD-128, YDF-170, ZX-1059, and ST-3000 manufactured by NIPPON STEEL Chemical & Material CO., LTD.; EPICLON 830, 835, 840, and 850, N-730A, and N-695 manufactured by DIC Corporation; and RE-306 manufactured by Nippon Kayaku Co., Ltd.

Examples of the polyfunctional oxetane compound include polyfunctional oxetanes such as bis[(3-methyl-3-oxetanylmethoxy)methyl]ether, bis[(3-ethyl-3-oxetanylmethoxy)methyl]ether, 1,4-bis[(3-methyl-3-oxetanylmethoxy)methyl]benzene, 1,4-bis[(3-ethyl-3-oxetanylmethoxy)methyl]benzene, (3-methyl-3-oxetanyl)methylacrylate, (3-ethyl-3-oxetanyl)methylacrylate, (3-methyl-3-oxetanyl)methylmethacrylate, (3-ethyl-3-oxetanyl)methylmethacrylate, and an oligomer or an copolymer thereof; and, in addition to those, examples include an etherification product of oxetanealcohol with a resin having a hydroxyl group such as novolak resin, poly(p-hydroxy styrene), cardo-type bisphenols, calixarenes, calixresorcinarenes, or silsesquioxane. Besides, examples include a copolymer of an unsaturated monomer having an oxetane ring and alkyl (meth)acrylate.

Examples of the compound having plural cyclic thioether groups in the molecule include bisphenol A-type episulfide resin. In addition, an episulfide resin obtained by replacing an oxygen atom of the epoxy group of novolak-type epoxy resin with a sulphur atom using the same synthesis method can be used as well.

Examples of the amino resin such as a melamine derivative or a benzoguanamine derivative include a methylol melamine compound, a methylol benzoguanamine compound, a methylol glycoluril compound, and a methylolurea compound.

As the isocyanate compound, a polyisocyanate compound can be combined. Examples of the polyisocyanate compound include: aromatic polyisocyanates such as 4,4′-diphenylmethane diisocyanate, 2,4-tolylene diisocyanate, 2,6-tolylene diisocyanate, naphthalene-1,5-diisocyanate, o-xylylene diisocyanate, m-xylylene diisocyanate, and a 2,4-tolylene dimer; aliphatic polyisocyanates such as tetramethylene diisocyanate, hexamethylene diisocyanate, methylene diisocyanate, trimethyl hexamethylene diisocyanate, 4,4-methylene bis(cyclohexyl isocyanate), and isophorone diisocyanate; aliphatic polyisocyanates such as bicycloheptane triisocyanate; and an adduct product, biuret product, and isocyanurate product of the isocyanate compound listed earlier.

As the blocked isocyanate compound, an addition reaction product of the isocyanate compound and the isocyanate blocking agent can be used. Examples of the isocyanate compound that can react with the isocyanate blocking agent include the above polyisocyanate compound. Examples of the isocyanate blocking agent include: a phenolic blocking agent; a lactam blocking agent; an active methylene-based blocking agent; an alcohol-based blocking agent; an oxime-based blocking agent; a mercaptan-based blocking agent; an acid amide-based blocking agent; an imide-based blocking agent; an amine-based blocking agent; an imidazole-based blocking agent; and an imine-based blocking agent.

In a case where the curable resin composition contains an alkali-soluble resin, the amount of the thermosetting component combined is such that the number of functional groups of the thermosetting component that reacts with respect to 1 mol of the carboxyl group contained in the alkali-soluble resin is preferably 0.5 to 2.5 mol and more preferably 0.8 to 2.0 mol in terms of solid content.

Further, a thermosetting catalyst is preferably added to and combined with the curable resin composition in addition to the above thermosetting component. Examples of a heat-curing catalyst include imidazole, imidazole derivatives such as 2-methylimidazole, 2-ethylimidazole, 2-ethyl-4-methylimidazole, 2-phenylimidazole, 4-phenylimidazole, 1-cyanoethyl-2-phenylimidazole, and 1-(2-cyanoethyl)-2-ethyl-4-methylimidazole; dicyandiamide, amine compounds such as benzyldimethylamine, 4-(dimethylamino)-N,N-dimethylbenzylamine, 4-methoxy-N,N-dimethylbenzylamine, and 4-methyl-N,N-dimethylbenzylamine; hydrazine compounds such as adipic dihydrazide and sebacic dihydrazide; and phosphorus compounds such as triphenylphosphine. In addition, examples of one that is commercially available include 2MZ-A, 2MZ-OK, 2PHZ, 2P4BHZ, 2P4MHZ (all are trade names of imidazole-based compounds), which are manufactured by Shikoku Chemicals Corporation; and U-CAT, 3513N (trade names of dimethyl amine compounds), DBU, DBN, U-CAT SA 102 (all are bicyclic amidine compounds and salts thereof) which are manufactured by San-Apro Ltd. The catalyst is not in particular limited to these; and may be a heat-curing catalyst for an epoxy resin or an oxetane compound, or one that promotes a reaction of at least one kind of an epoxy group and an oxetanyl group with a carboxyl group. The catalyst may be used solely; or two or more kinds thereof may be mixed to be used.

Further, guanamine, acetoguanamine, benzoguanamine, and S-triazine derivatives such as 2,4-diamino-6-methacryloyloxyethyl-S-triazine, 2-vinyl-2,4-diamino-S-triazine, a 2-vinyl-4,6-diamino-S-triazine.isocyanuric acid adduct, and a 2,4-diamino-6-methacryloyloxyethyl-S-triazine.isocyanuric acid adduct can be used. Preferably, these compounds which function also as adhesion imparting agents are used in conjunction with the heat-curing catalyst. One kind of heat-curing catalyst may be solely used, or two or more kinds may be used in combination.

Heat-curing catalysts other than those described above may be further included, and examples thereof are phenol resin, polycarboxylic acids and their acid anhydrides, cyanate ester resin, and active ester resin.

As the phenol resin, one kind of conventionally known phenol resin as described following can be used solely; or two or more kinds can be used in combination: phenol novolac resin, alkylphenol novolak resin, bisphenol A novolac resin, dicyclopentadiene type phenol resin, Xylok type phenol resin, terpene-modified phenol resin, cresol/naphthol resin, polyvinyl phenols, phenol/naphthol resin, α-naphthol skeleton-containing phenol resin, and triazine-containing cresol novolac resin.

The polycarboxylic acids and their acid anhydrides are compounds having two or more carboxyl groups in one molecule and their acid anhydrides, and examples thereof include (meta)acrylic acid copolymer, copolymer of maleic anhydride, and dibasic acid condensate as well as a resin having a carboxylic acid terminal such as a carboxylic acid terminal imide resin.

The cyanate ester resin is a compound having two or more cyanate ester groups (—OCN) in one molecule. As the cyanate ester resin, any conventionally known resin can be used. Examples of the cyanate ester resin include phenol novolac type cyanate ester resin, alkylphenol novolak type cyanate ester resin, dicyclopentadiene type cyanate ester resin, bisphenol A type cyanate ester resin, bisphenol F type cyanate ester resin, and bisphenol S type cyanate ester resin. Further, the cyanate ester resin may be a prepolymer which is partially triazinized.

The active ester resin is a resin having two or more active ester groups in one molecule. The active ester resin can be in general obtained by a condensation reaction between a carboxylic acid compound and a hydroxy compound. An active ester compound obtained by using a phenol compound or a naphthol compound as the hydroxy compound is particularly preferable. Examples of the phenol compound or naphthol compound include hydroquinone, resorcinol, bisphenol A, bisphenol F, bisphenol S, phenolphthalin, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, fluoroglucin, benzene triol, dicyclopentadienyl diphenol, and phenol novolac.

Moreover, an alicyclic olefin polymer may be used as the heat-curing catalyst. Specific examples of a method of producing an alicyclic olefin polymer include: (1) a method of polymerizing an alicyclic olefin having at least one of a carboxyl group and a carboxylic acid anhydride group (hereinafter referred to as “carboxyl group or the like”) together with a different monomer, if necessary; (2) a method of hydrogenating an aromatic ring moiety of a (co)polymer obtained by polymerizing an aromatic olefin having a carboxyl group or the like together with a different monomer, if necessary; (3) a method of copolymerizing an alicyclic olefin having no carboxyl group or the like with a monomer having a carboxyl group or the like; (4) a method of hydrogenating an aromatic ring moiety of a copolymer obtained by copolymerizing an aromatic olefin having no carboxyl group or the like and a monomer having a carboxyl group or the like; (5) a method of introducing a compound having a carboxyl group or the like into an alicyclic olefin polymer having no carboxyl group or the like by a degeneration reaction; and (6) a method of converting a carboxylic acid ester group of an alicyclic olefin polymer having a carboxylic acid ester group obtained as described in (1) to (5) above into a carboxyl group by, for example, hydrolysis or the like.

Among the heat-curing catalysts, phenol resin, active ester resin, and cyanate ester resin are preferable.

The above heat-curing catalyst is preferably combined in a ratio such that the ratio of a functional group capable of a heat-curing reaction to occur such as an epoxy group of a thermosetting resin to a functional group in a heat-curing catalyst that reacts with the functional group is as follows: the functional group of the heat-curing catalyst/the functional group capable of a heat-curing reaction to occur (equivalent ratio)=0.2 to 2.0 in terms of solid content. By setting the functional group of the heat-curing catalyst/the functional group capable of a heat-curing reaction to occur (equivalent ratio) within the above range, it is possible to prevent the surface of the cured film from being roughened in the desmear step. More preferably, the functional group of the heat-curing catalyst/the functional group capable of a heat-curing reaction to occur (equivalent ratio) is 0.3 to 1.0.

In the present invention, from the viewpoint of improving the physical strength of the insulating film for electronic components obtained by using the dry film and adjusting the matte feeling of the surface, the curable resin composition is preferably combined with a filler as necessary. As the filler, a known inorganic or organic filler can be used; an inorganic filler is more preferable, and barium sulfate, spherical silica, hydrotalcite, and talc are still more preferable. Further, a metal oxide, a metal hydroxide such as aluminum hydroxide, or the like can be used as an extender pigment filler for the purpose of imparting flame retardance.

The amount of the filler combined is not particularly limited, but is preferably 25% to 80% by mass based on the total amount of the composition in terms of solid content from the viewpoint of viscosity, coating property, formability, and the like.

Further, the above filler may be surface-treated in order to enhance the dispersibility in the curable resin composition. Aggregation can be suppressed by using a surface-treated filler. The surface treatment method is not particularly limited, and a commonly used known method may be used. However, it is preferable to treat the surface of the inorganic filler with a surface treatment agent having a curable reactive group, for example, a coupling agent having a curable reactive group as an organic group.

As the coupling agent, coupling agents such as silane-based, titanate-based, aluminate-based, and zircoaluminate-based coupling agents can be used. Of these, a silane-based coupling agent is preferable. Examples of such a silane-based coupling agent can include vinyl trimethoxysilane, vinyl triethoxysilane, N-(2-aminomethyl)-3-aminopropylmethyl dimethoxysilane, N-(2-aminoethyl)-3-aminopropyl trimethoxysilane, 3-aminopropyl triethoxysilane, 3-anilinopropyl trimethoxysilane, 3-glycydoxypropyl trimethoxysilane, 3-glycydoxypropylmethyl dimethoxysilane, 2-(3,4-epoxycyclohexyl)ethyl trimethoxysilane, 3-methacryloxypropyl trimethoxysilane, and 3-mercaptopropyl trimethoxysilane. These can be used solely or in combination. It is preferable that these silane-based coupling agents are previously immobilized on the surface of the filler by adsorption or reaction. Here, the amount treated by the coupling agent with respect to 100 parts by mass of the filler is preferably 0.5 to 10 parts by mass.

The curable resin composition may contain a colorant as necessary. As the colorant, a known colorant such as red, blue, green, or yellow can be used; and it may be any of pigment, dye, and coloring matter. Note that it is preferably a colorant that does not contain halogens from the viewpoint of reduction of environmental load and effects on the human body.

As the red color colorant, monoazo-based, disazo-based, azo lake-based, benzimidazolone-based, perylene-based, diketopyrrolopyrrole-based, condensed azo-based, anthraquinone-based, quinacridone-based red color colorant, and the like are available; and specific examples thereof include those given Colour Index International (C.I.; published by The Society of Dyers and Colourists) numbers as shown below.

Examples of the monoazo-based red color colorant include Pigment Red 1, 2, 3, 4, 5, 6, 8, 9, 12, 14, 15, 16, 17, 21, 22, 23, 31, 32, 112, 114, 146, 147, 151, 170, 184, 187, 188, 193, 210, 245, 253, 258, 266, 267, 268, and 269. Further, examples of the disazo-based red color colorant include Pigment Red 37, 38, and 41. Further, examples of the monoazo lake-based red color colorant include Pigment Red 48:1, 48:2, 48:3, 48:4, 49:1, 49:2, 50:1, 52:1, 52:2, 53:1, 53:2, 57:1, 58:4, 63:1, 63:2, 64:1, and 68. Further, examples of the benzimidazolone-based red color colorant include Pigment Red 171, 175, 176, 185, and 208. Further, examples of the perylene-based red color colorant include Solvent Red 135, 179, Pigment Red 123, 149, 166, 178, 179, 190, 194, and 224. Further, examples of the diketopyrrolopyrrole-based red color colorant include Pigment Red 254, 255, 264, 270, and 272. Further, examples of the condensed azo-based red color colorant include Pigment Red 220, 144, 166, 214, 220, 221, and 242. Further, examples of the anthraquinone-based red color colorant include Pigment Red 168, 177, and 216, Solvent Red 149, 150, 52, and 207. Further, examples of the quinacridone-based red color colorant include Pigment Red 122, 202, 206, 207, and 209.

As the blue color colorant, phthalocyanine-based and anthraquinone-based colorants are available. Examples of the pigment-based colorant include compounds classified as Pigment, for example, Pigment Blue 15, 15:1, 15:2, 15:3, 15:4, 15:6, 16, and 60. As the dye-based blue color colorant, Solvent Blue 35, 63, 68, 70, 83, 87, 94, 97, 122, 136, 67, 70, and the like can be used. Besides, metal-substituted or unsubstituted phthalocyanine compounds can be sued as well.

As the yellow color colorant, monoazo-based, disazo-based, condensed azo-based, benzimidazolone-based, isoindolinone-based, anthraquinone-based yellow color colorants, and the like are available; and examples of the anthraquinone-based yellow color colorant include Solvent Yellow 163, Pigment Yellow 24, 108, 193, 147, 199, and 202. Examples of the isoindolinone-based yellow color colorant include Pigment Yellow 110, 109, 139, 179, and 185. Examples of the condensed azo-based yellow color colorant include Pigment Yellow 93, 94, 95, 128, 155, 166, and 180.

Examples of the benzimidazolone-based yellow color colorant include Pigment Yellow 120, 151, 154, 156, 175, and 181. Further, examples of the monoazo-based yellow color colorant include Pigment Yellow 1, 2, 3, 4, 5, 6, 9, 10, 12, 61, 62, 62:1, 65, 73, 74, 75, 97, 100, 104, 105, 111, 116, 167, 168, 169, 182, and 183. Further, examples of the disazo-based yellow color colorant include Pigment Yellow 12, 13, 14, 16, 17, 55, 63, 81, 83, 87, 126, 127, 152, 170, 172, 174, 176, 188, and 198.

Besides, a colorant such as violet, orange, brown, black, or white may be added. Specific examples thereof include Pigment Black 1, 6, 7, 8, 9, 10, 11, 12, 13, 18, 20, 25, 26, 28, 29, 30, 31, and 32; Pigment Violet 19, 23, 29, 32, 36, 38, and 42; Solvent Violet 13 and 36; C.I. Pigment Orange 1, 5, 13, 14, 16, 17, 24, 34, 36, 38, 40, 43, 46, 49, 51, 61, 63, 64, 71, and 73; Pigment Brown 23 and 25; carbon black; and titanium oxide.

The amount of the colorant combined in the curable resin composition is not particularly limited, but it is preferably 0.1% to 5% by mass based on the total amount of the resin composition in terms of solid content.

The curable resin composition may contain an organic solvent from the viewpoint of the ease of preparation and coating property when forming the curable resin layer. As the organic solvent, commonly-used known organic solvents can be used, which include: ketones such as methyl ethyl ketone and cyclohexanone; aromatic hydrocarbons such as toluene, xylene, and tetramethylbenzene; glycol ethers such as cellosolve, methyl cellosolve, butyl cellosolve, carbitol, methyl carbitol, butyl carbitol, propylene glycol monomethyl ether, dipropylene glycol monomethyl ether, dipropylene glycol diethyl ether, diethylene glycol monomethyl ether acetate, and tripropylene glycol monomethyl ether; esters such as ethyl acetate, butyl acetate, butyl lactate, cellosolve acetate, butyl cellosolve acetate, carbitol acetate, butyl carbitol acetate, propylene glycol monomethyl ether acetate, dipropylene glycol monomethyl ether acetate, and propylene carbonate; aliphatic hydrocarbons such as octane and decane; and petroleum solvents such as petroleum ether, petroleum naphtha, and solvent naphtha. One kind of organic solvent can be used solely; or two or more kinds can be used in combination.

The amount of the organic solvent combined in the curable resin composition can be changed as appropriate depending on the material constituting the curable resin composition. In a case where the organic solvent is combined, the amount may be, for example, 5% to 90% by mass based on the total amount of the resin composition.

In addition, the curable resin composition may further be combined as necessary with an elastomer, a mercapto compound, a thixotropic agent, an adhesion promoter, a block copolymer, a chain transfer agent, a polymerization inhibitor, a copper damage inhibitor, an antioxidant, an anti-rust agent, a thickener such as organic bentonite or montmorillonite, at least one kind of antifoaming agents and leveling agents based on silicone, fluorine, polymer, and the like, and a flame retardant of a phosphorus compound such as hypophosphorous acid, a phosphate ester derivative, or a phosphazene compound. As for these, products known in the field of electronic materials can be used.

The curable resin layer can be formed by diluting the above curable resin composition with an organic solvent to adjust to an appropriate viscosity; applying the dilution on the surface of the above support using a comma coater, a blade coater, an LIP coater, a rod coater, a squeeze coater, a reverse coater, a transfer roll coater, a gravure coater, a spray coater, a bar coater, or the like such that a uniform thickness is attained on the support; and drying the coating usually at a temperature of 50° C. to 130° C. for 1 to 30 minutes. The thickness of the coating film is not in particular restricted; and is in general selected as appropriate in a range of 1 to 150 μm and preferably 10 to 60 μm in the thickness after the drying.

### [Protective Film]

For the purpose of preventing dust and the like from adhere to the surface of the curable resin layer and concurrently improving the operatability and the like, the protective film may be further provided on the side of the dry film opposed to the side of the curable resin layer in contact with the support.

As the protective film, a polyester film, a polyethylene film, a polytetrafluoroethylene film, a polypropylene film, paper subjected to a surface treatment, and the like can for example be used. A material is preferably selected such that adhesion between the protective film and the curable resin layer is smaller than adhesion between the support and the curable resin layer. In addition, at the time of using the dry film, the surface that contact with the curable resin layer of the protective film may be subjected to the anti-sticking treatment described above for the purpose of making the detachment of the protective film easier.

The thickness of the protective film is not in particular restricted and is selected as appropriate in a range of approximately 10 to 150 μm according to the application.

### [Method of Forming Insulating Film for Electronic Components Using Dry Film]

An insulating film for electronic components can be formed using the above dry film. A method of forming an insulating film for electronic components and a method of producing an electronic component which includes the above cured product (insulating film for electronic components) on a board on which a circuit pattern is formed will be described below. As an example of use in a case where the dry film is photosensitive, a method of producing an electronic component using the dry film that includes the protective film will be described.

i) First, the protective film is detached from the dry film to expose the curable resin layer.

ii) Then, the curable resin layer of the dry film is laminated on the electronic component on which a circuit pattern is formed.

iii) Exposure is carried out from above the support of the dry film.

iv) The support is detached from the dry film and development is carried out, thereby forming the curable resin layer that is patterned on the board.

v) The curable resin layer patterned is cured by light irradiation or heating to form an insulating film.

Thus, an electronic component that includes an insulating film can be produced. It is to be noted that in a case where the dry film that does not have a protective film is used, it goes without saying that the step of detaching the protective film (step i) is not needed. Each of the steps will be described below.

First, the protective film is detached from the dry film to expose the curable resin layer; and the curable resin layer of the dry film is laminated on the electronic component. Examples of the electronic component can include a board on which a circuit pattern is formed. Examples of the board on which a circuit pattern is formed can include, in addition to printed wiring boards on which a circuit is in advance formed and flexible printed wiring boards, all grades (FR-4 and the like) of copper clad laminates that use materials of copper clad laminates for high frequency circuit using paper phenol, paper epoxy, glass cloth epoxy, glass polyimide, glass cloth/non-woven fabric epoxy, glass cloth/paper epoxy, synthetic fiber epoxy, fluorine resin.polyethylene.polyphenylene ether, polyphenylene oxide.cyanate ester, or the like, other polyimide films, PET films, glass boards, ceramic boards, and wafer boards.

To laminate the curable resin layer of the dry film on the electronic component, lamination is preferably carried out using a vacuum laminator or the like under applied pressure and heating. By using such a vacuum laminator, no air bubbles are mixed and improved filling up dents of the electronic component surface is seen because the curable resin layer is closely attached to the electronic component. The applied pressure condition is preferably about 0.1 to 2.0 MPa; and the heating condition is preferably 40° C. to 120° C.

Next, exposure (irradiation of an active energy ray) is carried out from above the support of the dry film. By this step, the exposed curable resin layer is exclusively cured. The exposure step is not in particular restricted. The exposure may selectively be carried out by, for example, a contact method (or a noncontact method), through the photomask in which the desired pattern is formed using an active energy ray; or a desired pattern may be formed by exposure using a direct patterning apparatus by an active energy ray.

An exposure apparatus used for the active energy ray irradiation only need to be an apparatus that includes a high-pressure mercury vapor lamp, an ultrahigh pressure mercury vapor lamp, a metal halide lamp, LED, or the like, and radiates an ultraviolet ray of 350 to 450 nm. Further, a direct patterning apparatus (for example, a laser direct imaging apparatus that directly draws picture images using a laser based on CAD data from a computer) can also be used. A source of laser light of the direct patterning equipment may be either a gas laser or a solid laser as long as it employs a laser light with a maximum wavelength in a range of 350 to 410 nm. The exposure amount for the picture image formation varies in film thickness and the like, and can in general be set to a range of 20 to 800 mJ/cm² and preferably 20 to 600 mJ/cm². Further, the exposure light may be scattered light or parallel light.

After exposure, the support is detached from the curable resin layer and development is carried out, thereby forming the curable resin layer that is patterned on the electronic component. In the curable resin layer at the non-patterned portion, the surface of the curable resin layer is formed to have roughness morphology by exposure through the support. As long as the characteristics are not impaired, exposure may be performed after the support is detached from the curable resin layer after being laminated on the electronic component.

A photomask described in the method of forming an insulating film using a curable resin composition described later may be used. In such a case, it is preferable to use a support that does not have the above pattern, and the support may be exposed and developed after detaching the support from the dry film before exposure to the extent that the characteristics are not impaired.

The development step is not particularly restricted; a dipping method, a shower method, a spray method, a brush method, or the like can be employed. Further, as a development liquid, an aqueous solution of alkali such as potassium hydroxide, sodium hydroxide, sodium carbonate, potassium carbonate, sodium phosphate, sodium silicate, ammonia, amines, or tetramethylammonium hydroxide can be used.

Subsequently, the curable resin layer patterned is cured by active energy ray (light) irradiation or heating to form an insulating film for electronic components. This step is called final curing or additional curing, promotes the polymerization of unreacted monomers in the exposed curable resin layer, and further can proceed thermal curing of carboxyl group-containing photosensitive resin and the epoxy resin to reduce the amount of remaining carboxyl group. The active energy ray irradiation can be carried out in the same manner as described in the above exposure; and preferably carried out in a stronger condition than the irradiation energy at the time of the exposure. For example, the irradiation energy can be set to 500 to 3000 mJ/cm². In addition, the thermal curing can be carried out in a heating condition of about 100° C. to 200° C. for 20 to 90 minutes. It is to be noted that the final curing is preferably is carried out after the photo-curing. By carrying out the photo-curing before the thermal curing, the flow of the resin may be inhibited even at the time of the thermal curing and the incorporated surface may be maintained.

The above method of producing an insulating film for electronic components uses a dry film formed from a photocurable and thermosetting resin composition as the curable resin composition. A method of producing an insulating film for electronic components using a dry film formed from a photocurable resin composition or a thermosetting resin composition will also be described below.

In a case where an insulating film is formed only by photo-curing, for example, after laminating the curable resin layer of the dry film on an electronic component, an insulating film for electronic components may be formed by irradiation with active energy rays (for example, 1,000 to 2,000 mJ/cm²) to cure the curable resin layer.

In a case where an insulating film is formed only by heat-curing, for example, after laminating the curable resin layer of the dry film on an electronic component, an insulating film for electronic components may be formed by heating (for example, at a temperature of 100° C. to 220° C. for 30 to 90 minutes) to cure the curable resin layer.

The support is detached either before or after curing, but is detached preferably after curing of the curable resin composition. In addition to the above methods, it is possible to incorporate a prescribed surface morphology to the surface of the dry coating film of the curable resin composition using a transfer roller or the like or to use a dry film obtained by applying a curable resin composition to a support having a surface that has been processed into a specific shape in advance and drying it; however, the formation method is not limited thereto.

### [Electronic Component]

Examples of the electronic component provided with an insulating film according to the present invention can include, in addition to printed wiring boards on which a circuit is in advance formed with copper or the like and flexible printed wiring boards, all grades (FR-4 and the like) of copper clad laminates that use materials of copper clad laminates for high frequency circuit using paper phenol, paper epoxy, glass cloth epoxy, glass polyimide, glass cloth/non-woven fabric epoxy, glass cloth/paper epoxy, synthetic fiber epoxy, fluorine resin.polyethylene.polyphenylene ether, polyphenylene oxide.cyanate, or the like, other wafer boards, metal boards, polyimide films, polyethylene terephthalate films, polyethylene naphthalate (PEN) films, glass boards, ceramic boards, and wafer substrates. Of these, copper clad laminates are particularly preferable.

The insulating film for electronic components according to the present invention is useful as a permanent coating film for a printed wiring board such as a solder resist, a coverlay, and an interlayer insulating layer, and is particularly useful as a cured coating film for a solder resist. In particular, it can be suitably used for applications that require a matte-like insulating film. Further, it can be used not only for applications that require a patterned insulating film, but also for applications that do not require patterning, such as molding applications (sealing applications). In addition, it can also be suitably used for the formation of solder resist layer for IC package.

### Examples

By way of example, the present invention will be described in detail below. However, the present invention is by no means limited to the examples.

### Preparation of Support

### Support 1

An iso-butylated melamine resin (Amidia L-125-60 manufactured by DIC Corporation, solid content: 60%) and acrylic resin for melamine baking (ACRYDIC A-405 manufactured by DIC Corporation, solid content: 50%) were blended such that the blending ratio was set to 25:75 (in terms of solid content) on a mass basis, and the mixture was pre-stirred with a stirring apparatus, thereby obtaining an acrylic melamine resin.

Subsequently, the obtained acrylic melamine resin was diluted with methyl ethyl ketone to prepare a resin solution having a solid content concentration of 35% by mass. Methyl ethyl ketone was further added to this resin solution so as to the solid content concentration as appropriate according to the thickness of the coating film. Then, a silicone resin (Salmac US-270 manufactured by Toagosei Co., Ltd.) and a filler (SO-C2, spherical silica, manufactured by Admatechs Company Limited) adjusted to have a maximum particle size of 2 μm were added such that the blending ratio of the acrylic melamine resin, the silicone resin, and the filler was set to 59.7:0.3:108 on a mass basis. The mixture was thoroughly stirred at room temperature, thereby obtaining a uniform coating liquid.

The obtained coating liquid was applied to a polyethylene terephthalate film (E5041 manufactured by TOYOBO Co., Ltd.) with a thickness of 25 μm and dried at 130° C. for 20 seconds to prepare a support 1 including an intermediate layer. The total thickness of the support was 27 μm.

### Support 2

A support 2 including an intermediate layer was prepared in the same manner as the support 1 except that the blending ratio of the acrylic melamine resin, the silicone resin, and the filler was changed to 59.7:0.3:84.0. The total thickness of the support was 27 μm.

### Support 3

A support 3 including an intermediate layer was prepared in the same manner as the support 1 except that the blending ratio of the acrylic melamine resin, the silicone resin, and the filler was changed to 59.7:0.3:72.0. The total thickness of the support was 27 μm.

### Support 4

A polyethylene terephthalate film (E5041 manufactured by TOYOBO Co., Ltd.) with a thickness of 25 μm was used as a support 4.

### Support 5

A kneaded matte film (PTHA manufactured by UNITIKA Ltd.) with a thickness of 25 μm was used as a support 5.

### Support 6

A support 6 including an intermediate layer was prepared in the same manner as the support 1 except that the blending ratio of the acrylic melamine resin, the silicone resin, and the filler was changed to 59.7:0.3:48.0. The total thickness of the support was 30 μm.

### [Preparation of Curable Resin Compositions]

A four-necked flask equipped with a stirring apparatus and a reflux condenser was charged with 220 g of a cresol novolak type epoxy resin (EPICLON N-695 manufactured by DIC Corporation, epoxy equivalent: 220), 214 g of carbitol acetate was added, and the mixture was heated and dissolved. Next, 0.1 g of hydroquinone as a polymerization inhibitor and 2.0 g of dimethylbenzylamine as a reaction catalyst were added. The mixture was heated to 95° C. to 105° C., 72 g of acrylic acid was gradually added dropwise, and the mixture was reacted for 16 hours. The reaction product was cooled to 80° C. to 90° C., 106 g of tetrahydrophthalic anhydride was added, the mixture was reacted for 8 hours and cooled, and then the resultant was collected. The resin varnish of alkali-soluble resin thus obtained had a solid content of 65%, a solid acid value of 100 mgKOH/g, and a weight average molecular weight (Mw) of about 3,500.

One hundred (100) parts by mass of the alkali-soluble resin varnish (in terms of solid content), 30 parts by mass of dipentaerythritol hexaacrylate (DPHA manufactured by Nippon Kayaku Co., Ltd.) as a photosensitive monomer, 10 parts by mass of 2-[4-(methylthio)benzoyl]-2-(4-morpholinyl)propane (Omnirad 907 manufactured by IGM Resins B.V.) as a photocuring catalyst, 0.5 parts by mass of ethanone, 1-[9-ethyl-6-(2-methylbenzoyl)-9H-carbazole-3-yl]-,1-(0-acetyloxime) (Irgacure OXE02 manufactured by BASF Japan Ltd.), 0.5 parts by mass of 2,4-diethylthioxanthone (KAYACURE DETX-S manufactured by Nippon Kayaku Co., Ltd.) as a sensitizer, 20 parts by mass of bisphenol A type epoxy resin (EPICLON 840-S manufactured by DIC Corporation) as a thermosetting component, parts by mass of 1,3,5-tris(2,3-epoxypropyl)-1,3,5-triazine-2,4,6(1H, 3H, 5H)-trion (high melting point type, TEPIC-HP manufactured by Nissan Chemical Corporation), 90 parts by mass of barium sulfate (B-30 manufactured by Sakai Chemical Industry Co., Ltd.) as a filler, and 0.8 parts by mass of blue colorant (C.I. Pigment Blue 15: 3), 0.3 parts by mass of yellow colorant (C.I. Pigment Yellow 147), and 1.2 parts by mass of red colorant (Paliogen Red K3580 manufactured by BASF Japan Ltd.) as colorants were combined and mixed in advance using a stirring apparatus, and then kneaded using a three-roll mill, thereby preparing a curable resin composition.

To the curable resin composition obtained as described above, 300 g of methyl ethyl ketone was added to dilute and the resultant was stirred for 15 minutes using a stirring apparatus, thereby obtaining a coating liquid. The coating liquid was applied to the surface of each support described above (or the coated surface of a support having a coated surface) and dried at a temperature of 90° C. for 15 minutes to form a curable resin layer with a thickness of 20 μm after drying. A polypropylene film (OPP-FOA manufactured by Futamura Chemical Co., Ltd.) with a thickness of 18 μm was then laminated on the curable resin layer to prepare a dry film.

[Preparation of insulating Film for Electronic Components]

The surface of the copper clad laminate board (95 mm×150 mm×1.6 mmt) was subjected to chemical polishing. The polypropylene film was detached from the dry film obtained as described above; and the curable resin layer of the dry film was laminated on the surface of the side of the board subjected to the surface polishing. Subsequently, thermal laminating was carried out using a vacuum laminator (MVLP-500 manufactured by Meiki Co., Ltd.) in conditions of a degree of applied pressure: 0.8 Mpa, 70° C., one minute, a degree of vacuum: 133.3 Pa to closely adhere the board with the curable resin layer. Next, the resin layer was completely cured by heating at 150° C. for 60 minutes to form an insulating film.

### [Evaluation of Insulating Film for Electronic Components]

### [Measurement of Maximum Peak Height Rp, Maximum Valley Depth Rv, and Skewness Rsk on the Insulating Film Surface]

For each insulating film formed as described above, the maximum peak height Rp and the maximum valley depth Rv on the surface were measured in a shape measurement mode using a shape measurement laser microscope (VX-100 manufactured by KEYENCE CORPORATION).

As a specific measurement method, an observation application (VK-H1XV) was booted, a sample to be measured was placed statically on the XY stage, and the 50× objective lens was focused by autofocus in the shape measurement mode. The Z-axis was controlled as necessary to adjust the focus to the optimum position. Observation images were captured in the automatic measurement mode or the manual measurement mode. Next, an analysis application (VK-H1XA) was booted, and measurement was started.

As the measurement conditions, the evaluation range was set to 270 μm×202 μm. The Rp, Rv, and Rsk values of 10 evaluation points were measured at equal Intervals from the center to the outside of the sample, and the averages of the respective values were defined as maximum peak height Rp, maximum valley depth Rv, and skewness Rsk. The measurement results for each insulating film are shown in Table 1 below.

### [Measurement of Gloss on Insulating Film Surface]

Gs (60°) and Gs (85°) on the surface of the insulating film were measured using a digital variable angle gloss meter (Micro-Tri-Gloss manufactured by BYK-Gardener Gmbh). The value of Gs (85°)/Gs (60°) was calculated from the measurement results. The measurement results for each insulating film are shown in Table 1 below.

### [Measurement of Contact Angle]

The contact angle of water was measured and analyzed by the perfect circle fitting method under the following conditions using DropMaster DM300 as a contact angle meter and FAMAS (both manufactured by Kyowa Interface Science Co., Ltd.) as an integrated interface measurement and analysis system.
Boot the interface measurement analysis integrated system and start the CA/PD controller. At that time, select “Standard” for “Field of view” on the screen of the controller. Next, fill a plastic syringe with water, attach a stainless-steel needle (No. 22 gauge) to the tip of the syringe, and drop the water onto the evaluation surface. Make sure that the camera attached to the contact angle meter is in focus when dripping. Immediately after dripping, press the “Measurement” button on the controller screen.
Water used for measurement: Ion-exchanged water with a quality of treated water of 0.7 μS/cm or less produced by a system (Purelite PRO-0250-003 manufactured by Organo Corporation).
Amount of water dropped: 2 μL
Measurement temperature: 20° C.
Lens field of view: Standard

Subsequently, the contact angle immediately after dropping water was measured at any five points on the dry coating film placed horizontally, and the average value was defined as the contact angle of water. Here, the values of the contact angles at any five points were set to the values automatically calculated by pressing the “Measurement” button.

Further, with respect to the supports 1 to 6, the contact angle of the support surface to be coated with the curable resin composition was measured in the same manner as described above.

The contact angles of the water of the insulating films and the supports 1 to 6 were as shown in Table 1 below.

### [Evaluation of Marking Ink Bleed]

Screen printing was performed using a marking ink (S-100 W CM29 manufactured by TAIYO HOLDINGS CO., LTD.) and a #250 screen plate on the surface of each insulating film such that a pattern with a film thickness of 20 μm and line/space=200 μm/200 μm was formed after curing, and the marking ink was cured at 140° C. for 30 minutes. The printed surface was observed with an optical microscope (500 magnifications), and the line width was measured. The evaluation criteria for bleed were as follows.

o: Observed line width is 210 μm or less.

x: Observed line width is more than 210 μm.

The evaluation results are shown in Table 1 below.

### [Evaluation of Matte Feeling]

The formed insulating film was illuminated with a fluorescent lamp, the state of the fluorescent lamp reflected on the surface of the insulating film was visually observed, and the matte feeling was evaluated according to the following evaluation criteria.

o: The image of the fluorescent light is blurred.

x: The image of the fluorescent light is clearly reflected.

The evaluation results are shown in Table 1 below.

TABLE 1

| | | | | | Comparative | Comparative | Comparative |
|---|---|---|---|---|---|---|---|
| | | Example 1 | Example 2 | Example 3 | Example 1 | Example 2 | Example 3 |
| Support | | 1 | 2 | 3 | 4 | 5 | 6 |
| Rsk of support (μm) | | 0.04 | 0.04 | 0.02 | 0.25 | 2.58 | 1.40 |
| Contact angle of the support surface | | 76 | 76 | 75 | 70 | 70 | 93 |
| to be coated with the curable resin | | | | | | | |
| composition (°) | | | | | | | |
| Insulating | Rp (μm) | 0.82 | 0.79 | 0.92 | 0.23 | 0.63 | 1.23 |
| film | Rv (μm) | 1.59 | 1.13 | 1.10 | 0.48 | 3.67 | 4.5 |
| | Rv/Rp | 1.9 | 1.4 | 1.2 | 2.1 | 5.8 | 3.66 |
| | Rp + Rv (μm) | 2.28 | 1.92 | 2.02 | 0.70 | 4.26 | 5.69 |
| | Rsk (μm) | −0.06 | 0.04 | −0.02 | −0.26 | −3.00 | −1.45 |
| | Gs (85°) | 81 | 83 | 87 | 102 | 87 | 59 |
| | Gs (60°) | 7 | 8 | 17 | 99 | 44 | 5 |
| | Gs (85°)/Gs (60°) | 11.6 | 10.4 | 5.1 | 1.0 | 2.0 | 11.8 |

| | | | | | | |
|---|---|---|---|---|---|---|
| Contact angle of the surface of | 86 | 86 | 82 | 70 | 70 | 83 |
| insulating film (°) | | | | | | |
| Marking ink bleed | ∘ | ∘ | ∘ | x | x | x |
| Matte feeling | ∘ | ∘ | ∘ | x | ∘ | ∘ |

As is apparent from the evaluation results in Table 1, it is understood that when the maximum peak height Rp (μm) and the maximum valley depth Rv of the insulating film surface satisfy the relationship of 0.5≤Rv/Rp≤2 and 1≤Rp+Rv≤4, a good matte feeling can be obtained and marking ink bleed can be reduced. In addition, it is understood that also when Gs (85°)/Gs (60°) is 2 or more, Gs (85°) is 70 or more, and Gs (60°) is 30 or less, a good matte feeling can be obtained and marking ink bleed can be reduced.

Meanwhile, it is understood that the insulating film having an Rv/Rp of more than 2 and an Rp+Rv of less than 1 (Comparative Example 1) does not have a matte feeling, and the reduction of marking ink bleed is insufficient. In addition, it is understood that the insulating films having an Rv/Rp of more than 2 and an Rp+Rv of more than 4 (Comparative Examples 2 and 3) had a matte feeling, but the reduction of marking ink bleed is insufficient.

It is further understood that when Gs (85°)/(Gs (60°) is less than 2, there is no matte feeling, and the reduction of marking ink bleed is insufficient (Comparative Example 1). In addition, it is understood even when Gs (85°)/(Gs (60°) is 2 or more, if Gs (85°) is less than 70 or Gs (60°) is more than 30 (Comparative Examples 2 and 3), there is a matte feeling, but the reduction of marking ink bleed is insufficient.

1: An insulating film for electronic components having a front surface and a back surface, wherein a maximum peak height Rp (μm) and a maximum valley depth Rv (μm) of said front surface satisfying the following relational expressions:
0.5≤Rv/Rp≤2; and
1≤Rp+Rv≤4.

2: The insulating film for electronic components according to claim 1, wherein a skewness Rsk (μm) of said front surface is −0.1 or more.

3: A method of producing the insulating film or electronic components according to claim 1, the method comprising:
applying a curable resin composition to one side of a support, to form a coating film;
curing said coating film, to form an insulating film for electronic components; and
detaching said support,
wherein a skewness Rsk (μm) of the side of said support to which said curable resin composition is applied is 0.1 or less.

4: The method of producing the insulating film for electronic components according to claim 3, wherein when a contact angle of water on the side of said support to which said curable resin composition is applied is defined as B (°) and a contact angle of water on the surface of said insulating obtained is defined as A (°), the following relational expression is satisfied:
A>B.

5: An insulating film for electronic components having a front surface and a back surface,
wherein an 85° gloss, Gs (85°), and a 60° gloss, Gs (60°), of said front surface satisfy the following relational expression:
Gs(85°)≥2Gs(60°), and
wherein the Gs (85°) is 70 or more and the Gs (60°) is 30 or less.

6: The insulating for electronic components according to claim 1, comprising a heat-curing catalyst or a photocuring catalyst.

7: The insulating film for electronic components according to claim 1, comprising a filler.

8: The insulating film for electronic components according to claim 5, comprising a heat-curing catalyst or a photocuring catalyst.

9: The insulating film for electronic components according to claim 5, comprising a filler.
